(19) United States
(12) Patent Application Publication
(10) Pub. No.: US 2020/0098857 A1
(43) Pub. Date: Mar. 26, 2020

(54) NARROW-MESA SUPER-JUNCTION MOSFET

(71) Applicant: SEMICONDUCTOR COMPONENTS INDUSTRIES, LLC, Phoenix, AZ (US)

(72) Inventors: Gary H. LOECHELT, Tempe, AZ (US); Gordon M. GRIVNA, Mesa, AZ (US); Jaegil LEE, Incheon (KR); MinKyung KO, Bucheon (KR); Youngchul CHOI, Santa Clara, CA (US)

(73) Assignee: SEMICONDUCTOR COMPONENTS INDUSTRIES, LLC, Phoenix, AZ (US)

(21) Appl. No.: 16/141,761

(22) Filed: Sep. 25, 2018

(51) Int. Cl. H01L 29/06; H01L 29/08; H01L 29/423; H01L 21/762; H01L 29/66; H01L 21/225; H01L 21/764; H01L 29/78

(52) U.S. Cl. CPC H01L 29/0634; H01L 29/0649; H01L 29/0657; H01L 29/0865; H01L 29/4236; H01L 29/0696; H01L 21/3081; H01L 29/66712; H01L 29/0882; H01L 21/2251; H01L 21/764; H01L 29/7811; H01L 29/7813; H01L 21/76224

(57) ABSTRACT

A transistor device includes an n-doped pillar and a p-doped pillar forming a super-junction structure on a substrate. An isolation structure is disposed in a trench between the n-doped pillar and the p-doped pillar, and a source and a gate are disposed on the n-doped pillar. The isolation structure can include an air gap encapsulated in the trench by an oxide plug. The isolation structure can include an epi liner disposed on surfaces of the n-doped pillar and the p-doped pillar.

### TECHNICAL FIELD

The present disclosure relates to semiconductor devices such as a trench power metal-oxide-semiconductor field-effect transistor (MOSFET) device, and in particular, to a trench MOSFET device based on super-junction principles.

### BACKGROUND

Power MOSFETs based on super-junction principles (“super-junction MOSFET”) have become an industry norm, for example, for high-voltage switching applications. The super-junction MOSFETS have n-type and p-type column structures (super-junction structures) for charge balancing in the device mesas, which result in the super-junction MOSFETs having a lower drain-to-source on resistance (RDS(on)) and reduced gate and output charges than, for example, power MOSFETs based on planar technologies. These superior characteristics of a super-junction MOSFET enable, for example, efficient switching at any given frequency compared to a planar MOSFET.

Conventionally, the super-junction structures (i.e., the n-type and p-type columns) are fabricated using a multiple epitaxial layer and implant approach. However, the continuing miniaturization of electronic devices, cell pitches, and sizes of device features (e.g., mesas) imposes constraints on the super-junction technologies.

### BRIEF DESCRIPTION OF THE DRAWINGS

FIG. 1A is a block diagram schematically illustrating features of an example super-junction MOSFET.

FIG. 1B is a cross sectional view of a precursor stage of an example super-junction MOSFET illustrated in FIG. 1C.

FIG. 1C is a cross sectional view of the example super-junction MOSFET.

FIGS. 2-9 illustrate a series of cross-sectional views of a super-junction MOSFET through stages of an example fabrication process.

FIG. 10 shows a cross sectional view of another example super-junction MOSFET.

FIG. 11 is a plan view layout of an example narrow-mesa super-junction MOSFET.

FIG. 12 illustrates an example method for fabricating a super-junction transistor.

Like reference characters or numerals represent like elements throughout the various drawings.

### DETAILED DESCRIPTION

Vertical channel or trench gate metal-oxide-semiconductor field-effect transistor (MOSFET) devices may be used, for example, in power device applications. In a trench gate MOSFET device, the source, gate, and drain regions are arrayed in a vertical direction (e.g., y direction) of a semiconductor substrate (e.g., an n+ doped semiconductor substrate). Source and drain terminals may be placed on opposite sides of the semiconductor substrate, and a gate electrode may be disposed in dielectric material in a trench that is etched in the vertical direction (e.g., a y direction) perpendicular to a major surface of the semiconductor substrate. This vertical configuration may be suitable for a power MOSFET device, as more surface space can be used as a source, and also the source and drain separation can be reduced. Reduction of the source and drain separation can increase the drain-to-source current ratings and also can allow use of an epitaxial layer for the drain drift region to increase the voltage blocking capability of the device.

For high-voltage MOSFETs, the voltage blocking capability in the drain drift region is developed through the combination of a thick epitaxial layer and light doping. This results in a large portion of the device resistance being in the drain and limits the performance (e.g., RDS(on)) of the device. Often, there is a trade-off between breakdown voltage and on-resistance, because increasing the breakdown voltage by incorporating a thicker and lightly doped drain drift region in the device leads to a higher on-resistance.

For some devices, a super-junction principle allows a thick drift region of a power MOSFET (i.e., a super-junction MOSFET) to be heavily doped, thereby reducing the electrical resistance to electron flow without compromising the breakdown voltage. The heavily doped region (e.g., an n-doped region) is juxtaposed with a region that is similarly heavily P doped with the opposite carrier polarity (holes). These two similar, but oppositely doped regions effectively cancel out their mobile charge and develop a depleted region that supports the high voltage during the off-state. On the other hand, during the on-state, the higher doping of the drift region allows for the easy flow of carriers, thereby reducing on-resistance.

A super-junction MOSFET includes a drain structure (super-junction drain structure) in which multiple vertical pn junctions (formed by adjoining p-type and n-type columns) are arranged in the drain region as a result of which a low on-resistance RDS(on) and reduced gate charge Qgd can be realized while maintaining a high voltage. The n-type columns and p-type columns in the super-junction drain structure are fabricated incrementally, epi level-by-level, for example, by sequentially depositing, patterning, and doping (implanting) a number of epitaxial layers of semiconductor material on a semiconductor substrate. In such a super junction drain structure, a main current path (e.g., an n-doped column) may be more heavily doped (e.g., by a factor of 10) than for a conventional high-voltage MOSFET. This lowers the on-state resistance of the drain. The current path of the p-type and n-type columns may be dimensioned so that when the transistor is turning off and developing blocking voltage, a depletion region forms with migration of the charge carriers from the p-type columns resulting in a near-neutral space charge region and high blocking-voltage capability.

The difference in the amount of charge carriers in the n-type and p-type columns is referred to as charge balance. Charge balance depends on the physical and electrical characteristics and parameters of the super junction drain structure (and the device). Charge balance must be tightly controlled for good device performance. A high charge imbalance (i.e., charge balance values outside an acceptable range of values) can result in abrupt breakdown voltage (BV) drop and severe BV variation in the devices.

With continuing miniaturization of electronic devices, cell pitches, and sizes of device features (e.g., mesas), charge balance control in super-junction MOSFETs using traditional super junction drain structures becomes difficult (e.g., because of the overlap and inter-diffusion of dopants in adjacent n-doped and p-doped columns of the traditional super-junction structures fitted in the narrower mesas).

For a next generation of miniaturization, in order to reduce the specific RDS(on), the cell pitch will need to be reduced while maintaining the same total amount of charge per unit cell. At the same time, charge balance control can become more difficult, which will require better process control and/or design improvements to increase the charge balance window for performance improvements. The conventional multiple epi/implant approach for making a super-junction drain structure has difficulties in meeting these requirements. A smaller cell pitch requires more epi/implant steps, which increases the process cost. Further, the counter-doping and inter-diffusion of the dopants in the contiguous or adjacent n-doped and p-doped columns through the multiple epi/implant steps reduces the amount of free charge available for conduction. In order to compensate for this effect, the total amount of charge per unit cell must be increased, which further reduces the size of the charge balance window.

The super-junction MOSFET devices described herein are miniaturized devices, have a reduced specific RDS(on) with reduced cell pitches while maintaining relatively the same total amount of charge per unit cell. The super-junction MOSFET devices described herein have desirable charge balance control even with small and narrow device sizes. Also, in accordance with the principles of the present disclosure, inter-diffusion of dopants in the n-doped and p-doped columns in a super-junction drain structure of a super-junction MOSFET) can be reduced by disposing an isolation structure (i.e., a trench filled with isolation materials) between an n-doped pillar (column) and a neighboring p-doped pillar (column) in the super-junction drain structure. The isolation structure trench cuts through or separates an n-doped column and contiguous p-doped column (formed by complementary doping of epitaxial layers on a substrate) to form an n-doped pillar and a non contiguous neighboring p-doped pillar. In example implementations, the isolation structure may include an air gap or void (e.g., a gap filled with gas at atmospheric or sub-atmospheric pressures). The isolation structure may include a lightly-doped epi region disposed between the air gap and heavily-doped regions of the n-doped pillar and/or the neighboring p-doped pillar. In example implementations, the isolation structure can have a vertical depth (e.g., in a y direction) comparable to a vertical thickness of a drain region of the device (in the y direction). Further, the isolation structure may have a lateral width (e.g., in an x-direction)) parallel to an upper surface of semiconductor substrate. In example implementations, the lateral width of the isolation structure in a top or upper vertical portion of a super-junction drain structure may be substantially larger than the lateral width of the isolation structure in a lower vertical portion (lower body portion) of the super-junction drain structure. This lower body portion is distinct and separate from the trench bottom, where the trench sidewall transitions from a mostly vertical orientation to a more horizontal orientation.

The cross-sectional diagrams illustrated in the figures and described below are representative drawings. Processing variations, variations in aspect ratios, differences in design dimensions, and/or so forth can result in different shapes and/or non-idealities.

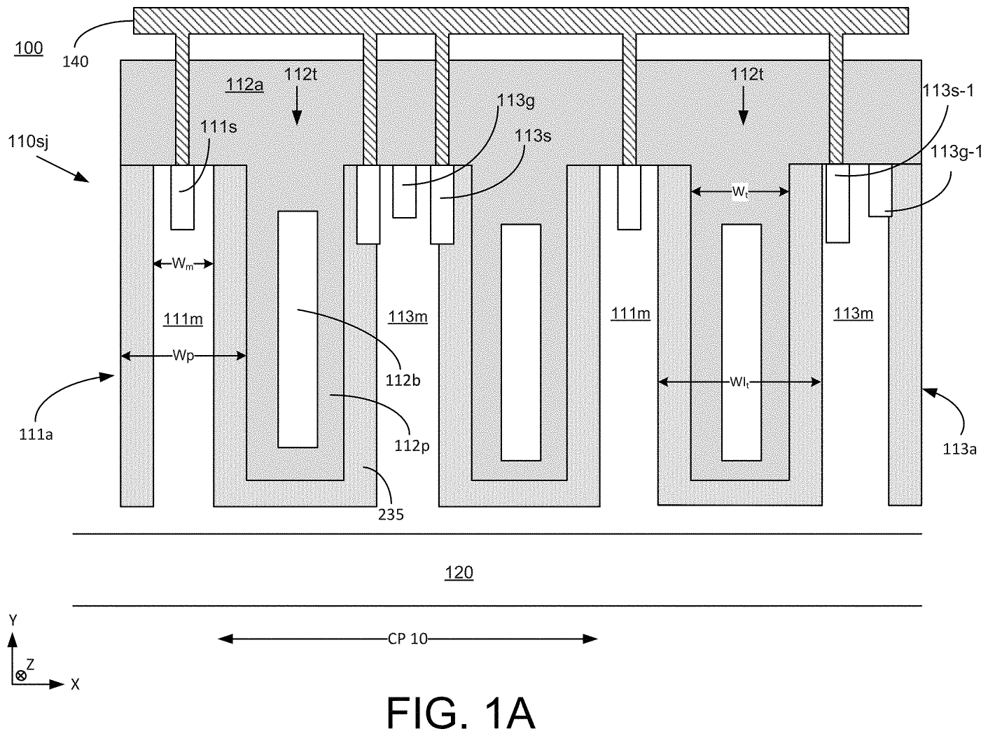

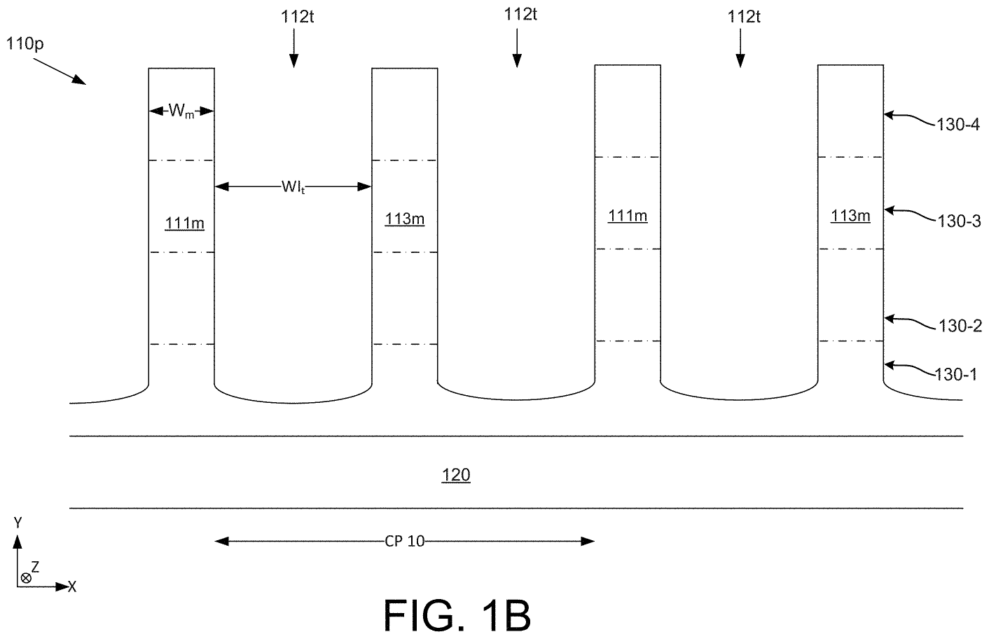

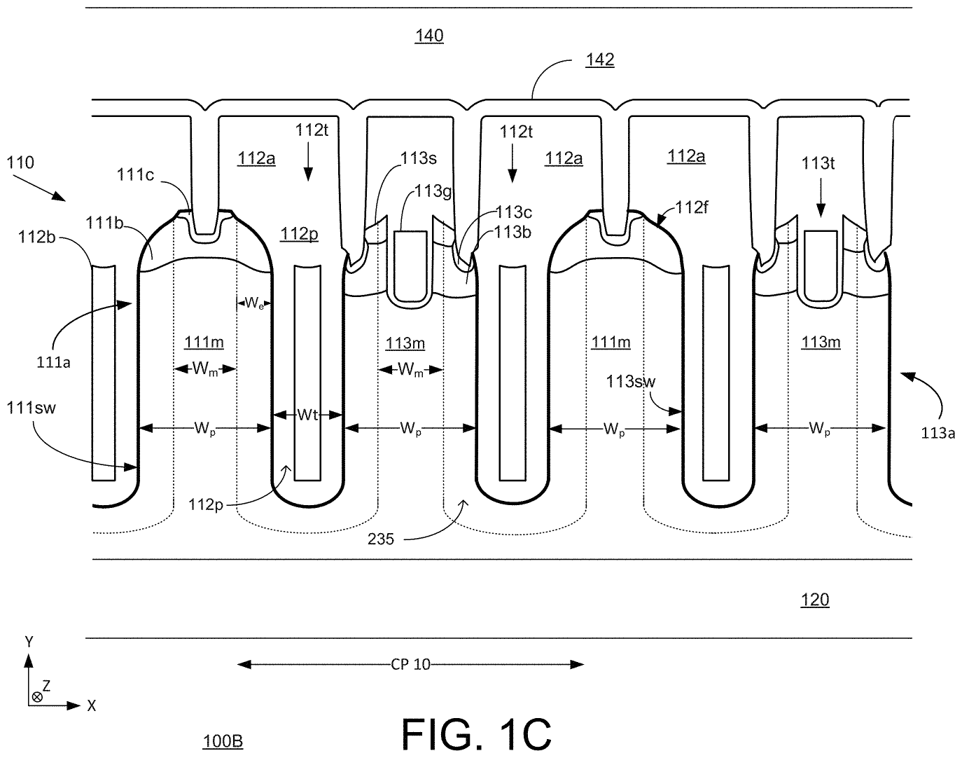

FIG. 1A is a block diagram schematically showing, in cross sectional view, features of an example super-junction MOSFET 100 (also can be referred to as a super-junction device or as a device), in accordance with the principles of the present disclosure. The super-junction MOSFET 100 shown in FIG. 1A includes a symmetrical device portion (on the left side) and an asymmetrical device portion (on the right side).

In FIGS. 1A, 1B, 1C, and 2-10 herein, features at a greater (or deeper) depth in the substrate are shown toward the bottoms of the figures and features at a lesser (or shallower) depth are shown toward the tops of the figures. Although some features are described in terms of an n-type device, the dopant types can be reversed.

As shown in FIG. 1A, super-junction MOSFET 100 has a super-junction drain structure 110sj (fabricated, for example, on a heavily doped semiconductor substrate 120 (e.g., n+ doped substrate)). Super-junction drain structure 100sj includes an alternating array of p-doped semiconductor mesas 111m (e.g., p-doped mesas) and n-doped semiconductor mesas 113m (e.g., n-doped mesas). Each of the mesas may have a mesa width Wₘ. The p-doped mesas and the n-doped mesas are non-contiguous. Each p-doped mesa and n-doped mesa in the array is physically separated from each other by a trench 112t (having an initial trench width WIₜ).

Trench 112t between a p-doped mesa and an n-doped mesa is filled with an isolation structure 112a. Isolation structure 112a can include two or more components that isolate the p-doped mesa 111m from the n-doped mesa 113m. A first component can be a lightly-doped or undoped epitaxial layer 235 grown on the sidewalls of trench 112t (i.e., on the surfaces of the mesas in the trench). While epitaxial layer 235 can be lightly-doped or undoped when first formed, epitaxial layer 235 becomes doped at higher levels (e.g., comparable to the doping levels of the adjoining mesa 111m or mesa 113m) due to thermal diffusion of dopants from the adjoining p-doped mesa 111m or n-doped mesa 113m during subsequent thermal processes in the fabrication of the device. A second component can be a dielectric material fill 112p (e.g., oxide plug) that isolates the p-doped mesa 111m from the n-doped mesa 113m and plugs and caps trench 112t. The dielectric material fill 112p can cap and seal an air gap 112b in a lower portion of trench 112t. Air gap 112b disposed in trench 112t can be a third component in isolation structure 112a between the p-doped mesa 111m and the n-doped mesa 113m.

In super-junction drain structure 110sj, epi liner 235 (grown on the sidewalls of trench 112t) increases the widths (e.g., Wₘ) of the semiconductor mesas to form semiconductor pillar structures (e.g., p-doped pillar 111a and n-doped pillar 113a) with wider widths Wₚ. A width Wₚ of a pillar can, for example, be a sum of the width of a mesa Wₘ and the thicknesses of the epi liners grown on two opposing vertical surfaces of the mesa.

The increased widths of the pillars (compared to the mesa widths) can provide additional semiconductor real estate for fabricating device components (e.g., gates, source and body regions, contact regions, etc.) of device 100. In example implementations, the n-doped pillars may be the main (primary) conductive path of current in the device. FIG. 1A shows an example in which a gate (e.g., gate 113g), and one or more source region(s) (e.g., source region 113s) are formed in an n-doped pillar 113a. In some example implementations, two source region 113s may be formed in a symmetrical arrangement about a gate 113g in an n-doped pillar 113a (as shown, for example, in pillar 113a that is second from the left in FIG. 1A). In some example implementations, a single source region 113s-1 and an off-center gate 113g-1 may be formed in an asymmetrical arrangement in an n-doped pillar 113a.

In super-junction drain structure 110sj, the p-doped pillars may provide holes to charge balance electrons of the current flowing through the n-doped pillars. For this purpose, the p-doped pillar 111a may include a body contact region 111s. A source metal 140 can make contact with body contact region 111s in the p-doped pillars and source regions 113s in the n-dope d pillars.

In an example implementation, super-junction device 100 may have a cell pitch (e.g., cell pitch CP 10) with two vertical trenches 112t and an intervening mesa per unit cell.

FIGS. 1B and 1C are diagrams that illustrate an implementation of the symmetrical portion of the super-junction MOSFET 100 shown in FIG. 1A. FIG. 1B shows a cross sectional view of a precursor stage of the example super-junction MOSFET 100B. FIG. 1C shows a cross sectional view of the example super-junction MOSFET 100B, in accordance with the principles of the present disclosure.

As shown in FIG. 1B, a precursor super-junction drain structure 110p may be fabricated in, or on, an epitaxial buffer layer 130-1 grown on a heavily doped semiconductor substrate (e.g., n+ doped substrate 120). The heavily doped semiconductor substrate 120 may be the drain of device 100B shown in FIG. 1C. Super-junction drain structure 110p (e.g., fabricated on epitaxial buffer layer 130-1) can include an array of alternating p-doped mesas 111m and n-doped mesas 113m. The array of alternating p-doped mesas 111m and n-doped mesas 113m may be fabricated initially as contiguous p-doped and n-doped columns (not shown), level-by-level, in a stack of a number of epitaxial layers (e.g., epi layers 130-1, 130-2, 130-3 and 130-4, etc.) by sequentially depositing, patterning, and doping (implanting) the number of epitaxial layers grown on substrate 120. Non-contiguous p-doped mesas 111m and n-doped mesas 113m are defined (i.e., cut from the contiguous p-doped and n-doped columns in the epitaxial layers) by vertical trenches 112t etched in the epitaxial layers on substrate 120. Each of the mesas (111m, 113m) may have a width Wₘ. Each vertical trench 112t may have an initial lateral opening width WIₜ that provides a separation distance or spacing between two neighboring mesas 111m and 113m.

In a super-junction drain structure 110 of fabricated device 100B (shown in FIG. 1C) based on super-junction drain structure 110p (shown in FIG. 1B), each vertical trench can hold an isolation structure separating an n-mesa (pillar) from a p-mesa (pillar). The isolation structure may include, for example, one or more different insulating materials. One of the insulating materials can be a solid dielectric material such as an oxide 111a. A second of the insulating materials can be a gas at atmospheric or sub-atmospheric pressures 113a. A lightly-doped or undoped epitaxial liner may widen the n-doped mesas and p-doped mesas to form wider pillar structures (e.g., p-doped pillars 111m and n-doped pillars 113m) (and, conversely, narrow the lateral opening width of trench 112t).

In an example implementation, a cell pitch (e.g., cell pitch CP 10) of super-junction device 100B may be on the order of a few microns (e.g., 2 μm, 4 μm, 10 μm) with two vertical trenches 112t and an intervening mesa per unit cell. Each vertical trench may have target depth of tens of microns (e.g., about 30 to 60 μm or about 40 to 50 μm) and an initial lateral opening width WIₜ (also can be referred to as a trench width) of a few microns (e.g., about 1 μm). In some implementations, the vertical trenches may have a depth of between 5 to 30 times greater than a cell pitch of the vertical trenches. In some implementations, the vertical trenches may have a depth of between 10 to 50 times greater than the initial opening width of the vertical trenches.

Each mesa (p-doped mesa 111m or n-doped mesa 113m) between the vertical trenches may have an initial width (Wₘ) of less than a micron (e.g., about 0.8 μm). In example implementations, a lightly-doped or undoped epitaxial silicon layer (epi liner) may be grown or deposited on surfaces of the mesas in the trenches. The epi liner may have a thickness or width (Wₑ), for example, of less than a micron (e.g., about 0.4 μm).

This epi liner (e.g., about 0.4 μm thick in some implementations) increases the width (Wₘ) of each mesa (p-mesa 111m or n-mesa 113m) to the widths (Wₚ) of the pillar structures (e.g., p-doped pillar 111a and n-doped pillar 113a). For example, a width (Wₘ) of about 0.8 μm of each mesa may be increased to a pillar width (Wₚ) of about 1.6 μm. Also, the epi liner (e.g., about 0.4 μm thick) reduces the initial opening width (WIt) (e.g., about 1.4 μm) of the vertical trenches to a narrower opening width Wₜ (e.g., about 0.6 μm).

In example implementations, p-doped pillars 111a and n-doped pillars 113a may, for example, have tops with rounded or tapered corners resulting in narrowed pillar widths at the tops. The rounded or tapered corners of the pillar tops, as shown in FIG. 1C, may correspond to an outward flare shape (e.g., flare 112f) in the width of trench 112t (filled by the isolation structure 112a) between a p-doped pillar 111a and an n-doped pillar 113a. In some implementations, the pillar tops can have a curved profile or shape. In some implementations, the pillar tops can slope in a downward direction from a center of the pillar top to an outer edge of the pillar top.

A main (e.g., primary) conductive path of the device may be through n-doped pillar 113a. N-doped pillar 113a accommodates the source and gate structures of the device. In an example, implementation, the device may have a gate width of about 0.4 μm.

In example implementations, a thermal oxide liner may be grown or deposited on sidewalls 111sw of p-doped pillars 111a and sidewalls 113sw of n-doped pillars 113a. This thermal oxide liner is depicted in FIG. 1C by the bold lines shown along sidewalls 111sw of p-doped pillars 111a and sidewalls 113sw of n-doped pillars 113a.

Isolation structures 112a may include, for example, a dielectric fill (e.g., oxide plug 112p, which may, for example, include deposited silicon oxide, TEOS oxide, boron-phosphor-silicate glass (BSPG), etc.) that plugs or caps a trench 112t between a p-doped pillar 111a and an n-doped pillar 113a. As shown in FIG. 1C, isolation structures 112a may also, for example, extend over the tops of the pillars.

In an example implementation, an isolation structure 112a between a p-doped pillar 111a and an n-doped pillar 113a can include a gas-filled (e.g., air-filled) cavity (e.g. air gap 112b) disposed between (e.g., interposed between) the adjoining pillars (i.e., between p-doped pillar 111a and n-doped pillar 113a). Air gap 112b may be formed when oxide plug 112p plugs or caps the upper portions of narrow trench 112t but does not completely fill the lower portions of trench 112t.

Isolation structure 112a may physically prevent thermally driven interdiffusion or intermixing of the dopants of the adjoining pillars, for example, during thermal processes used in fabricating super-junction device 100B.

In super-junction device 100B, an n-doped pillar 113a may include a gate structure 113g (e.g., gate poly and gate oxide) disposed in a trench 113t, n-doped source regions 113s adjoining gate structure 113g, and p-doped body regions 113b including ohmic contact regions 113c. P-doped pillars 111a, which provide holes for charge balance with the electrons of n-doped pillars 113a in the super-junction device, may include a p-doped body region 111b with an ohmic contact region 111c (which may be formed by the same or complementary processes used to form p-doped body regions 113b and ohmic contact regions 113c of the n-doped pillars). Contacts 111d and 113d extending from (or part of) a tungsten plug layer 142 may connect a source contact metal layer (e.g., source contact 140) to body regions 111b and 113b (via ohmic contact regions 111c and 113c, respectively). N-doped pillars 113a may be the main (e.g., primary) current path of the device (between source and drain).

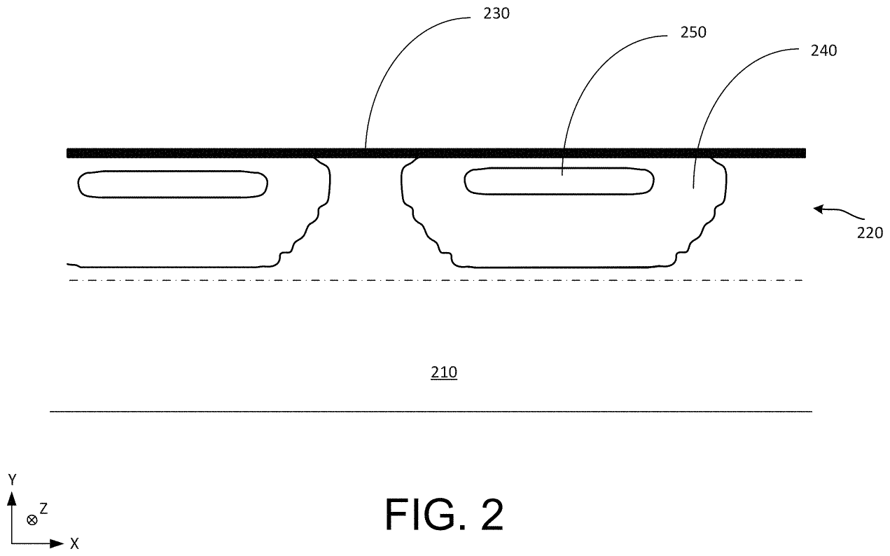

FIGS. 2 through 9 illustrate cross-sectional views of a substrate as it is being processed through multiple steps of an example semiconductor device fabrication process to fabricate a super-junction device (e.g., MOSFET device 100B, FIG. 1C), in accordance with the principles of the present disclosure. While like reference characters or numerals are used to label like elements throughout the various drawings, some of the elements are not labeled in some of the figures for visual clarity in views and simplicity in description.

The semiconductor device fabrication process shown in FIGS. 2-9 may be referred to as the process hereinafter. The multiple steps of the process may, for example, involve wafer level processing of a substrate 210, layer-by-layer. These steps may include, for example, photoresist coating, lithographic patterning, deposition, and removal of materials on (or of) the substrate. For convenience in description herein, the term substrate may refer to a starting unprocessed substrate and also to the substrate processed through each of the multiple steps of the process.

The process begins by selecting, for example, a heavily-doped semiconductor substrate (e.g., an arsenic (As) doped silicon substrate), and growing a buffer epitaxial layer on the substrate, which is then subject to a blanket As implant. A number of epitaxial layers (e.g., four layers) are then sequentially grown, level-by-level, on the buffer epitaxial layer. After each level, the epitaxial layer is patterned (in a photo lithographic step) to define a resist mask opening for receiving a phosphorus (P) implant for an n-doped column (not shown), and a resist mask opening for receiving a boron (B) implant for a p-doped column (not shown). The n-doped columns and p-doped columns are precursors of the n-doped pillars and the p-doped pillars of the super-junction structure of the device. In example implementations, the resist mask openings for receiving the P implant, and for receiving the B implant may, for example, be 2.2 μm mask openings in a 1.235 μm photoresist layer.

The last level epitaxial layer (e.g., a top epi layer) may be patterned (in a photo lithographic step) to define a resist mask opening for receiving a last boron (B) implant for the p-doped pillar.

FIG. 2 shows a cross sectional view of the substrate (e.g., substrate 210) at this stage of the process (i.e., with a hard mask oxide/nitride layer grown or deposited on the top epi layer.) In substrate 210, a hard mask oxide/nitride layer (e.g., layer 230) is grown or deposited on a top epi layer 220. Top epi layer 220 includes a heavily doped (boron doped) region 250 and a relatively lightly doped (boron doped) region 240 as a result of the last boron (B) implant for the p-doped pillar. In an example implementation, layer 230 may include 100 Å dry oxide and 450 Å deposited nitride.

Next, the hard mask oxide/nitride layer (e.g., layer 230) is photo lithographically patterned (in a photolithographic step) and etched to define openings for a deep silicon trench etch. In an example implementation, the deep silicon etch may be used to etch trenches 112t having a target depth, for example, of about 40 μm to 50 μm. Trenches 112t may physically cut through p-doped columns and n-doped columns in the epitaxial layers on substrate 210 to form separate non-contiguous mesas (i.e., p-doped mesas 111a and n-doped mesas 113a).

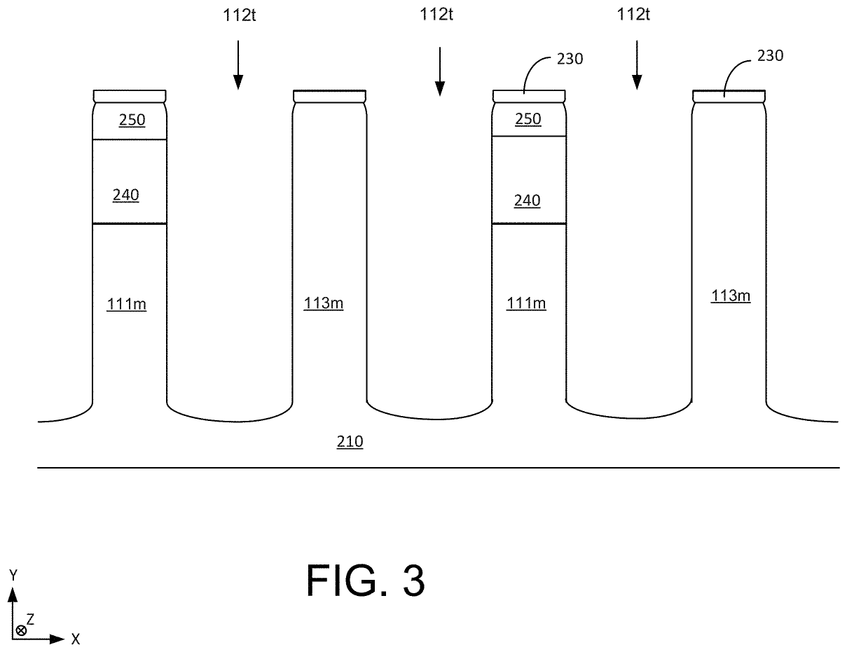

FIG. 3 shows a cross sectional view of the substrate (e.g., substrate 210) after the vertical trenches (e.g., trench 112t) that separate p-doped mesas 111m and n-doped mesas 113m have been etched. N-doped mesas 113m are doped with n-type dopant, for example, as a result of the P implants at each level of four epitaxial layers deposited or grown on substrate 210 by this stage of the process. Further, p-doped mesas 111m are doped with p-type dopant, for example, as a result of the B implants at each level of four epitaxial layers deposited or grown on substrate 210 by this stage of the process. P-doped mesas 111a, as shown in FIG. 3, may also include heavily doped (boron doped) region 250 and relatively lightly doped (boron doped) region 240 as a result of the last boron (B) implant for the p-doped mesa.

Further, sidewall protection oxide and nitride layers (not shown) may be deposited on the sidewalls of the vertical trenches (e.g., trench 112t) that separate p-doped mesas 111m and n-doped mesas 113m. The sidewall protection oxide and nitride layers may seal p-doped mesas 111m and n-doped mesas 113m for a drive-in anneal of the dopants (B, P) implanted in the mesas. The drive-in anneal may homogenize distribution of dopants in each p-doped mesa 111m and each n-doped mesa 113m (dopants B and P, respectively). The drive-in anneal conditions can be chosen such that the diffusion lengths for the dopants in the p-doped mesas 111m and n-doped mesas 113m are approximately equal to or greater than the thicknesses of the epitaxy layers (e.g., epi layers 130-1, 130-2, 130-3 and 130-4, etc.) in the super-junction drain structure.

After the drive-in anneal, the protective sidewall nitride and oxide may be removed (e.g., etched), and an undoped (or a lightly doped) epitaxial layer (epi liner 235) may be either selectively or non-selectively deposited or grown on the sidewalls of the vertical trenches (e.g., trench 112t) that separate p-doped mesas 111m and n-doped mesas 113m. The epi liner increases the widths of the mesas to form wider pillar structures (i.e., p-doped pillars 111a and n-doped pillars 113a).

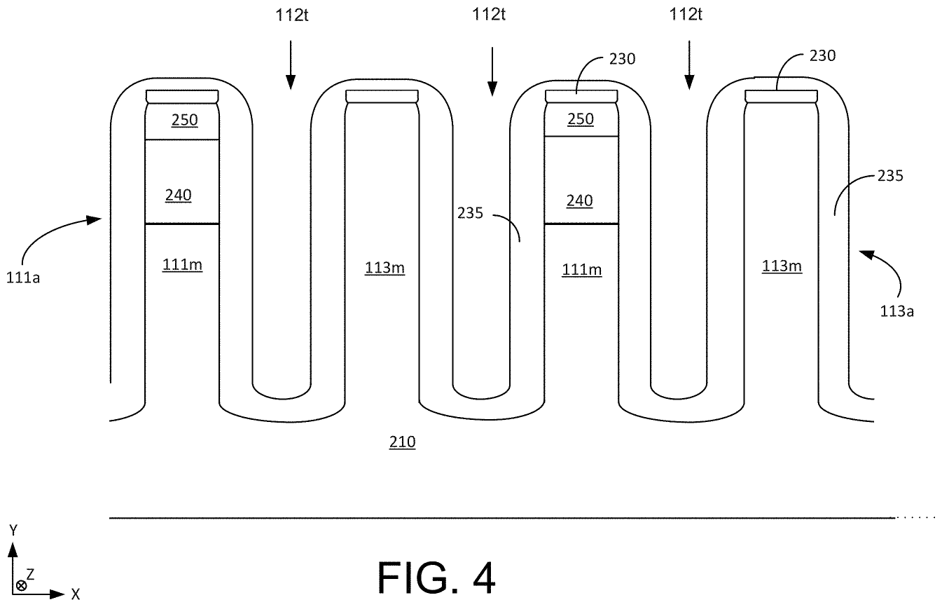

FIG. 4 shows a cross sectional view of the substrate (e.g., substrate 210) after the undoped epitaxial layer (e.g., epi liner 235) is deposited on the sidewalls of the vertical trenches 112t and the tops of mesas 111m and 113m to form p-doped pillars 111a and n-doped pillars 113a. In an example implementation, epi liner 235 may be an undoped epi layer, which is about 0.4 um thick. A purpose of epi liner 235 may be to narrow the widths of the trenches (e.g. trenches 112a) that will have to be subsequently filled or capped to form isolation structures (e.g., isolation structures 112a), and to widen the silicon mesas to form the wider p-doped pillars 111a and n-doped pillars 113a.

Further, a silicon recess etch may be used to recess or etch back the undoped epi layer (epi liner 235) deposited on the tops of pillars 111a and 113a to a level below the hard mask (e.g., layer 230) on top of the silicon mesas (i.e., p-doped mesa 111m and n-doped mesas 113m). In an example implementation, a 0.55 μm timed etch may be used to recess or etch back the undoped epi layer (epi liner 235) to the level below the hard mask. In the case where epi liner 235 is grown selectively, the time of the etch may be reduced or eliminated altogether.

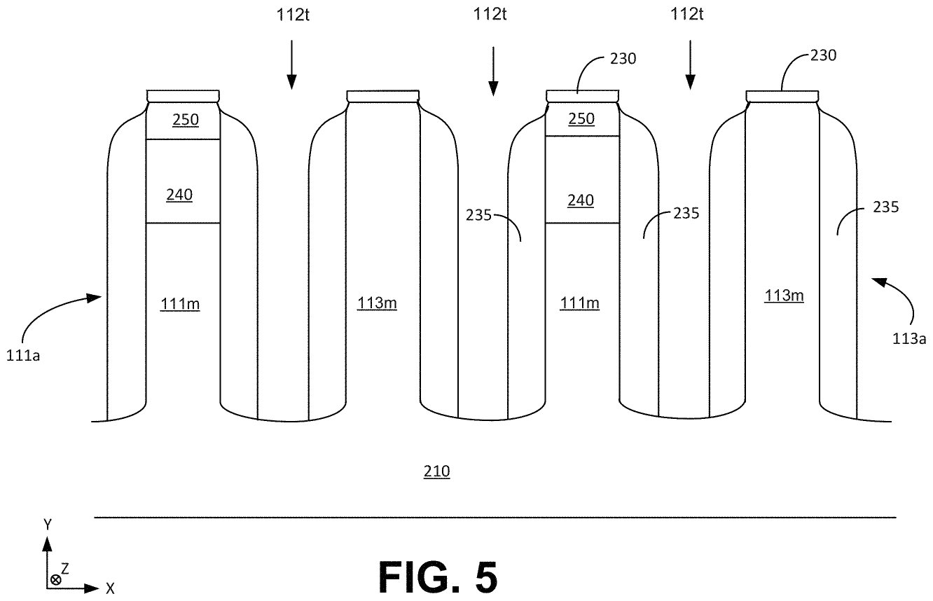

FIG. 5 shows a cross sectional view of the substrate (e.g., substrate 210) after etch back of the undoped epi layer (epi liner 235) to the level below the hard mask 230.

After the undoped epi layer etch back (which flares the tops of the trenches 112t outwardly, and rounds the top corners of p-doped pillars 111a and n-doped pillars 113a), a thermal oxide liner (not shown) may be grown on the sidewalls of the doped pillars (111a, 113a). In an example implementation, about 1200 Å wet oxide may be grown on the sidewalls of the pillars (111a, 113a) as the thermal oxide liner. This thermal processing (and subsequent thermal processes) can cause thermal diffusion of dopants into epi liner 235 from adjoining p-doped mesa 111m or n-doped mesa 113m. As a result, the initially lightly doped or undoped epi liner may have doping levels that are comparable to the doping levels of adjoining p-doped mesa 111m or n-doped mesa 113m.

Further, the process may include a sacrificial poly fill and etch back. In an example implementation, undoped poly (e.g., about 1.0 μm thick poly) may be deposited in trenches 112t and etched back so that top of the poly is recessed (e.g., by about 0.25 μm) below the top surface of substrate 210.

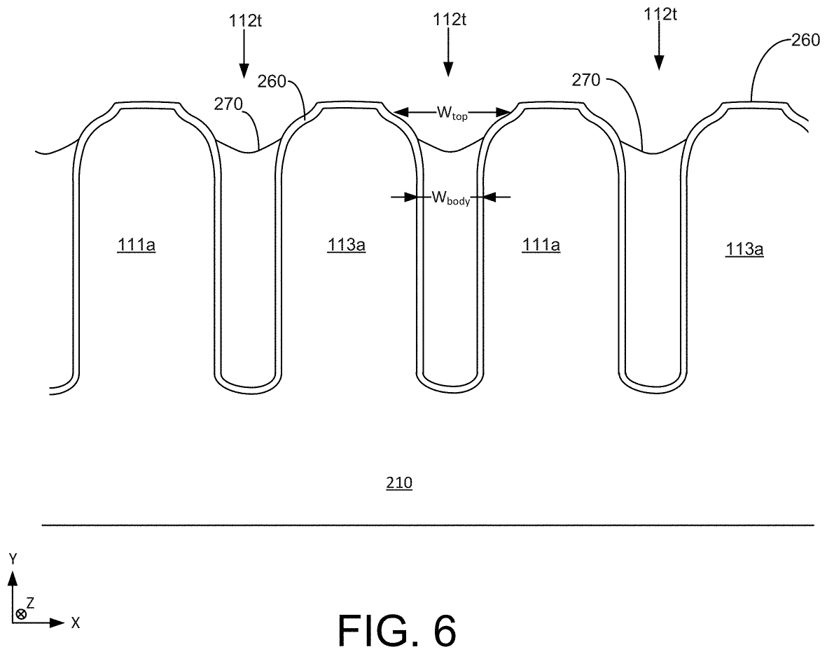

FIG. 6 shows a cross sectional view of the substrate (e.g., substrate 210) after the sacrificial poly fill and etch back. As shown in FIG. 6, a thermal oxide liner 260 is grown on the sidewalls of the doped pillars (111a, 113a). Further, the tops of p-doped pillars 111a and n-doped pillars 113a have a rounded or tapered corner shapes because of the epi growth and etch back. The rounding of the tops of p-doped columns 111a and n-doped columns 113a may be described equivalently, in other words, as the broadening of the widths of trenches 112t at about the tops of p-doped pillars 111a and n-doped pillars 113a. FIG. 6 shows, for example, trenches 112t as having a lateral width, Wₜₒₚ, (e.g., in x-direction) at about the tops of p-doped pillars 111a and n-doped pillars 113a, and a lateral width, W_{body}, in the body of the trench below, with Wₜₒₚ>W_{body}. The position at which W_{body} is measured is sufficiently above the bottom of the trenches to avoid any sidewall rounding at the bottom as previously noted.

Further steps in the process may relate to formation of the gate and source structures of a trench MOSFET in a pillar (e.g., in an n-doped pillar 113a). These steps may, for example, include etching a vertical trench to house a gate (e.g., a poly gate) of the device, forming a thermal gate oxide, gate poly fill and planarization, p-well formation (photolithography/implant/anneal), n-source formation (photolithography/implant/anneal), and a gate poly recess step. During these steps, which modify n-doped pillars 113a, the p-doped pillars (e.g. pillars 111a) may be masked or protected by a sacrificial oxide/nitride layer extending over the surface of substrate 210.

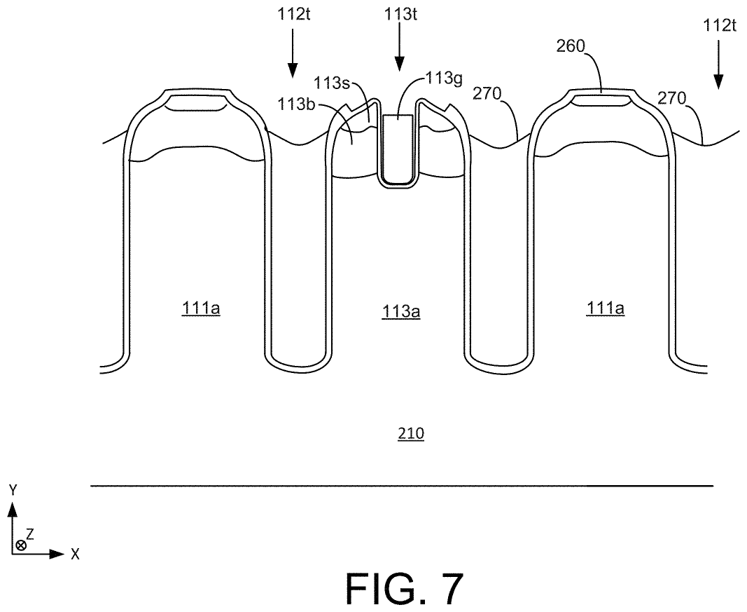

FIG. 7 shows a cross sectional view of the substrate (e.g., substrate 210) after a vertical trench (e.g., trench 113t) is etched to house the gate (e.g., gate 113g), and p-wells (e.g., body regions 113b) and source regions (e.g., source regions 113s) of the device are formed in an n-doped pillar 113a. In an example implementation, trench 113t (etched in n-doped pillar 113a) may have a target depth, for example, of about 1.2 μm. Gate 113g may be made of doped poly (e.g., about 0.8 μm thick doped poly). Further, two source regions 113s may be formed, for example, in a symmetrical arrangement on two sides of the gate trench (e.g., trench 113t). The source regions may be formed, for example, with an N+ source implant (e.g., 5.0×10¹⁵ atoms/cm² phosphorus @ 80 keV) through 2.2 μm mask openings.

Further steps in the process may involve removing the sacrificial poly fill (poly 270) from the trenches (e.g., trenches 112t) that separate p-doped pillars 111a and n-doped pillars 113a. In an example implementation, a photoresist mask has openings (e.g., 0.6 μm wide mask openings) centered over poly fill 270 in the trenches (e.g., trenches 112t). An isotropic silicon etch (e.g., a 50 μm minimum depth plus over etch) can be used to remove the sacrificial poly in the deep trenches 112t. Because trench oxide liner 260 protects the silicon in the pillars during the etch, a long over etch is possible.

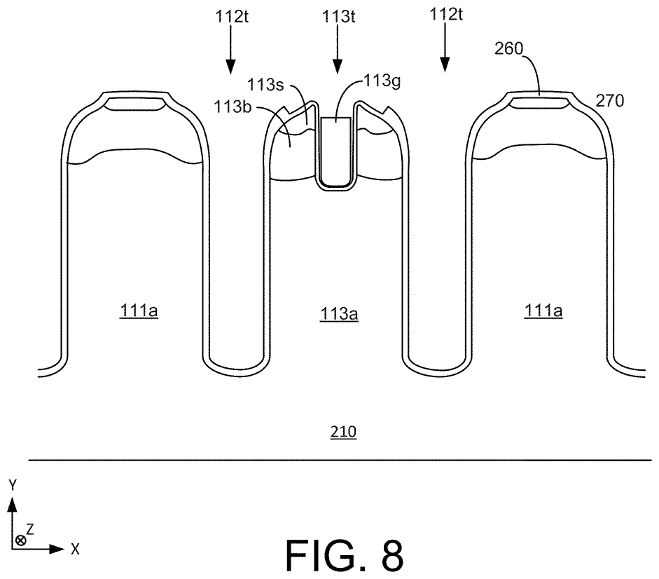

FIG. 8 shows a cross sectional view of the substrate (e.g., substrate 210) after the sacrificial poly is removed from the vertical trenches (e.g., trench 112t) that separate p-doped pillars 111a from n-doped pillars 113a.

Further steps in the process relate to completion of the isolation structures (e.g., isolation structures 112a) in the trenches (e.g., trenches 112t) that separate p-doped pillars 111a and n-doped pillars 113a. These steps may include a gate protect lithography step, a trench oxide plug and cap deposition step (that leaves an air gap in the trench), planarization, and interlayer dielectric (ILD) deposition.

In an example implementation, a trench oxide plug (e.g., oxide plug 290) can include an oxide layer (e.g., a 5000 Å thick oxide layer) formed, for example, by tetraethyl orthosilicate (TEOS) deposition. The oxide layer can be annealed on the substrate, and followed by a layer of deposited BPSG (e.g., a 8000 Å BPSG layer). After BPSG reflow, oxide chemical mechanical polishing (CMP) may be used to planarize substrate 210 so that an oxide layer remains. Oxide plug 290 may cover the tops of the p-doped pillars 111a and n-doped pillars 113a, but does not completely fill the deep trenches leaving an air gap (e.g., air gap 112b) in a lower portion of trenches 112t.

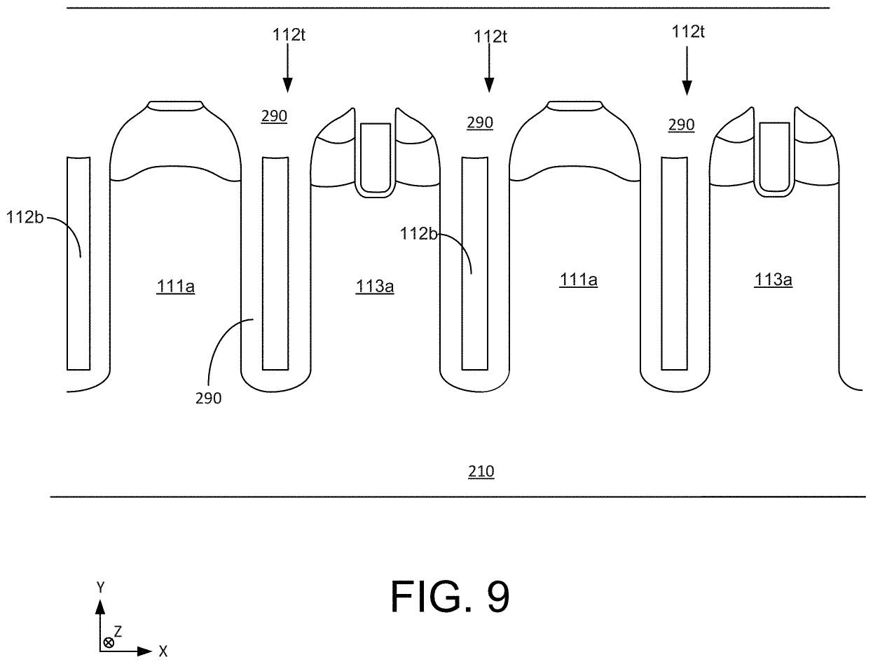

FIG. 9 shows a cross sectional view of the substrate (e.g., substrate 210) after air gaps 112b are formed in the vertical trenches (e.g., trenches 112t) that separate p-doped pillars 111a and n-doped pillars 113a. Air gap 112b is formed in a trench 112t by oxide plug 290 not completely filling the trench.

Further steps in the process relate to contact and metal formation. These steps may, for example, include forming a tungsten plug (e.g., plug 142, FIG. 1C) to make electrical contact between the source regions (e.g., source regions 113s) in the n-doped pillars of the device and a source contact metal (e.g., source metal 140), and between body regions 111b in the p-doped pillars of the device and source metal 140. These process steps can result in the super-junction MOSFET (e.g., device 100) shown, for example, in FIG. 1C.

Conventional MOSFETs with traditional super-junction structures may have specific RDS(on) values in the range of about 10 mΩ cm² to 16 mΩ cm². Simulations of a test super-junction MOSFET device (e.g., device 100, FIG. 1C) with super-junction drain structure 110 show that a specific RDS(on) of 5-6 mΩ cm² can be achieved for a 600V (BV) rated device. The test super-junction MOSFET device used for these simulations was a device having a threshold cell pitch of 4.4 μm, and with each p-doped pillar 111a and n-doped pillar 113a in the device having an initial mesa width of about 0.8 μm. A gate width of about 0.4 μm was used for the simulated device.

The simulations showed that further reductions in RDS(on) can be achieved by shrinking the cell pitch in the test super-junction device to below the initial test cell pitch of 4.4 μm (e.g., to cell pitches of 4 μm, 3 μm, 2 μm, etc.).

In example implementations, the same super-junction drain structure 110 and the same techniques (e.g., trench isolation, described with reference to FIGS. 1-9 above) for isolating the p-doped pillars from the n-doped pillars may be used in a super-junction device having a cell pitch smaller than a threshold cell pitch. The smaller size cell pitch can reduce the widths of the mesas (e.g., widths of the n-doped pillars) and thus the semiconductor (silicon) real estate available for forming the source and gate structures of the device. For example, for a device with a cell pitch of 4.0 μm and two trenches 112t per cell, using an example 1.4 μm wide trench technology may result in narrower mesas that have an initial width of only 0.6 μm (instead of the 0.8 μm mesas for a cell pitch of 4.4 μm). Since less semiconductor (silicon) area is available in the narrower mesas of a smaller cell pitch device, it can be difficult to form two source structures (source regions and source contacts) in a symmetrical arrangement (as shown in FIG. 1C) on two sides of the gate trench (e.g., trench 113t) on an n-doped pillar 113a (especially when the gate widths are kept the same for the different cell pitch devices).

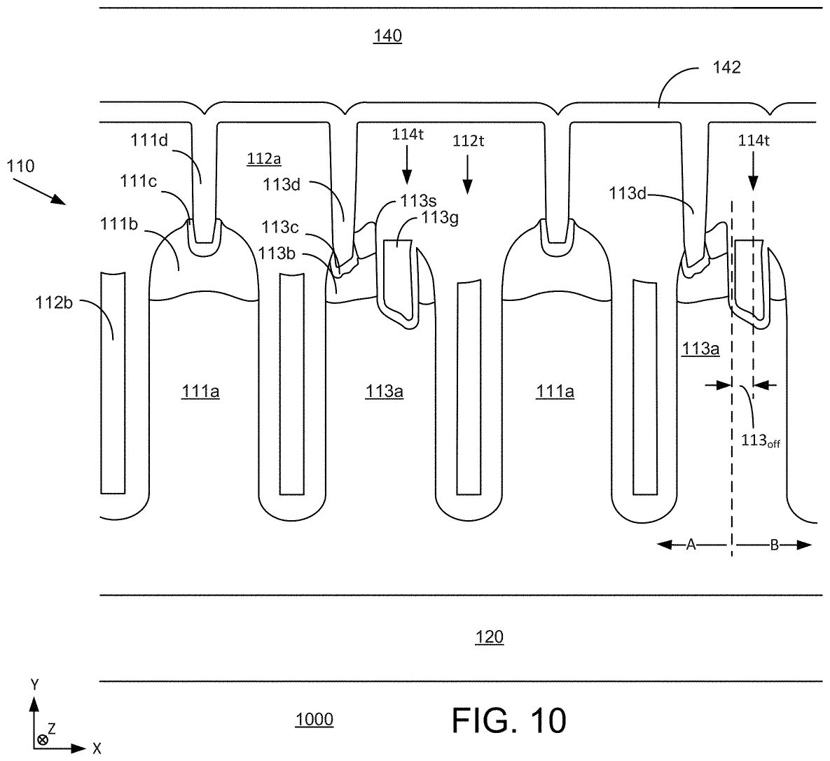

FIG. 10 shows a cross sectional view of an example narrow-mesa super-junction MOSFET device 1000 with a one-sided asymmetrical arrangement of source contacts and gates, in accordance with the principles of the present disclosure. FIG. 10 can be an implementation of the asymmetrical portion of the super-junction MOSFET 100 shown in FIG. 1A.

Narrow-mesa super-junction device 1000, like device 100 shown in FIG. 1A, may include super-junction drain structure 110 fabricated in or on an epitaxial buffer layer 130-1 grown on a heavily doped semiconductor substrate (e.g., n+ doped substrate 120). However, super-junction device 1000 may have a cell pitch of only about 4.0 μm resulting in narrow mesas for p-doped pillars 111a and n-doped pillars 113a. The initial mesa widths of the pillars (without oxide liner 235) in device 1000 may, for example, be only about 0.6 μm.

In device 1000 (like in device 100, FIG. 1A), the n-doped pillars (e.g., n-doped pillars 113a in which source and gate structures are built) may be the main (primary) current path of the device (between source and drain). In an example implementation, in consideration of the narrower mesa widths of n-doped pillar 113a in device 1000, the source and gate structures may include a trench gate (e.g., gate 113g) built off-center on one side (e.g., side B) of the mesa, and only one source/body contact may be built on the other side (e.g., side A) of the mesa. As shown in FIG. 10, the trench (e.g., trench 114t) housing gate 113g may be etched off-center on n-doped pillar 113a (e.g., at an offset distance 113_{off} from the center to side B of n-doped pillar 113a). Gate 113g in device 1000 (with a smaller cell pitch) can have the same critical dimensions (CD) as gate 113g in device 100 (with a larger cell pitch). Further, in device 1000, a source region (e.g., source region 113s), a body region (e.g., body region 113b), an ohmic contact region (e.g., ohmic contact 113c) are connected by a single contact 113d to source metal 140 (e.g., by contact 113d formed on the other side (e.g., side A) of the mesa). This one-sided asymmetrical arrangement of source contacts and gates on the narrower mesas of device 1000 uses less silicon area than the silicon area used by the two-sided symmetrical arrangement of source contacts and gates in device 100, while allowing use of the same gate CDs in both devices having different cell pitch.

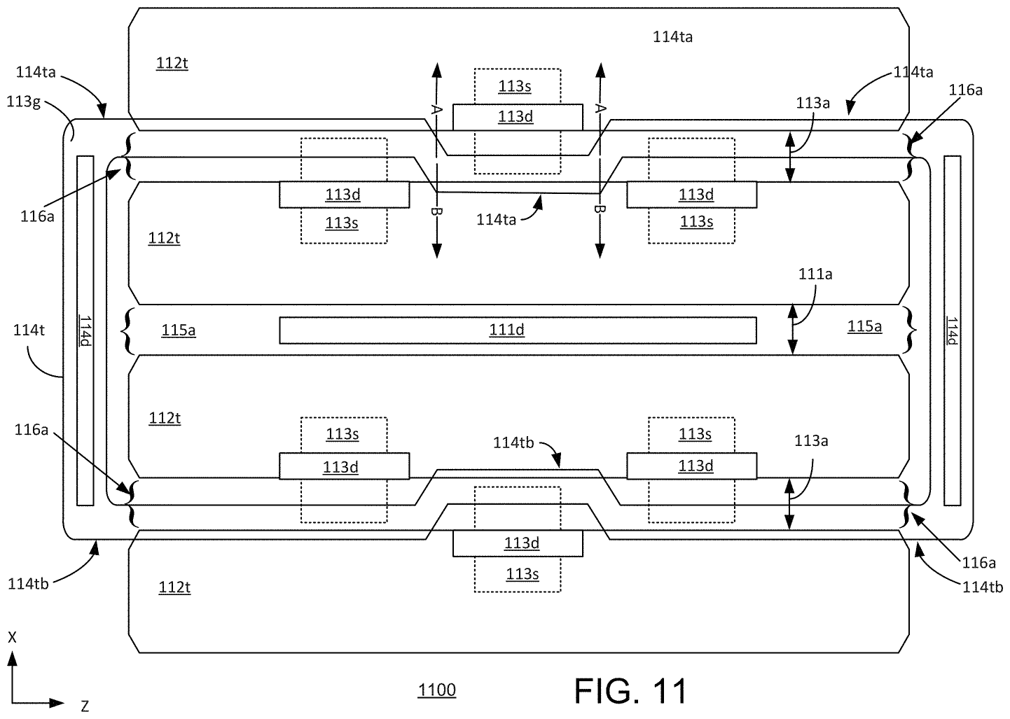

FIG. 11 shows a plan view layout of an example narrow-mesa super-junction MOSFET device 1100 with an alternating one-sided asymmetrical arrangement of source contacts and gates, in accordance with the principles of the present disclosure.

As shown in FIG. 11, the super-junction structure in device 1100 may include p-doped pillars 111a and n-doped pillars 113a formed by etching deep trenches 112t through n-doped columns and p-doped columns (not shown) grown on a semiconductor substrate. P-doped pillars 111a and n-doped pillars 113a (like trenches 112t) extend in the z-direction (e.g., as mesa stripes 115a of a first conductivity type (e.g., p-type) and mesa stripes 116a of a second conductivity type (e.g. n-type)). Device 1100 includes a gate trench loop (e.g., a rectangular loop formed by a gate trench 114t). One arm (arm 114ta) of the gate trench loop (shown in a top half of the figure) extends along mesa stripe 116a (pillar 113a) in the z direction and a return arm (arm 114tb)) of the gate trench loop (shown in a bottom half of the figure) extends along a parallel mesa stripe 116a (pillar 113a) in the negative z direction. Gate trench 114t holds gate 113g, which is connected to gate contacts 114d, for example, on the side arms of the rectangular trench loop.

In device 1100, n-source regions (e.g., source region 113s) and source contacts (e.g., contacts 113d) are placed on alternating sides (A, B) of n-doped pillars 113a along the lengths of the n-doped mesa stripes 116a (pillar 113a) in the z-direction. Gates 113g are placed opposite to the n-source regions on n-doped pillars 113a (i.e., on the opposite sides (B, A) of n-doped pillars 113a) along the lengths of the mesa stripes in the z-direction. This can be accomplished (as shown in a middle portion of FIG. 11) by shifting gate trench 114t (which holds gate 113g) from one side (e.g., side A) to the second side (e.g., side B) of mesa stripe 116a (pillar 113a) so that gate 113g is always on the side opposite to the side (A, B) on which any particular n-source region 113s is placed.

In the one-sided asymmetrical arrangement of source contacts and gates used in device 1100 (as shown in FIG. 11), having source contacts (113d) alternate on sides A and B of mesa stripe 116a (pillar 113a) allows charge to be extracted from both sides (A and B) of mesa stripe 116a (pillar 113a) via source contacts 113d. This configuration of source contacts may avoid build up of floating charges in mesa stripe 116a (pillar 113a).

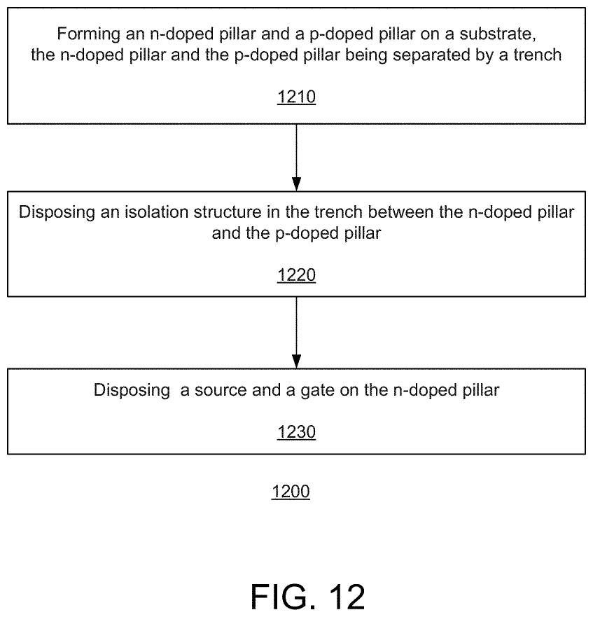

FIG. 12 shows an example method 1200 for fabricating a super-junction transistor. Method 1200 includes forming an n-doped pillar and a p-doped pillar on a substrate (1210). The n-doped pillar and the p-doped pillar are separated by a trench. Method 1200 further includes disposing an isolation structure in the trench between the n-doped pillar and the p-doped pillar (1220), and disposing a source and a gate of the transistor on the n-doped pillar (1230).

In method 1200, disposing the isolation structure in the trench between the n-doped pillar and the p-doped pillar 1220 includes disposing an oxide plug in the trench between the n-doped pillar and the p-doped pillar. The oxide plug may cap the trench and encapsulate an air gap in the trench. Disposing the isolation structure in the trench between the n-doped pillar and the p-doped pillar 1220 may further include disposing an epi liner between the isolation structure and the n-doped pillar and between the isolation structure and the p-doped pillar.

It will also be understood that when an device element, such as a source, drain, electrode, or dielectric layer or other device component, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Implementations of the various techniques described herein may be implemented in (e.g., included in) digital electronic circuitry, or in computer hardware, firmware, software, or in combinations of them. Portions of methods also may be performed by, and an apparatus may be implemented as, special purpose logic circuitry, e.g., an FPGA (field programmable gate array) or an ASIC (application-specific integrated circuit).

While certain features of the described implementations have been illustrated as described herein, many modifications, substitutions, changes and equivalents will now occur to those skilled in the art. It is, therefore, to be understood that claims, if appended, are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A device comprising:
an n-doped pillar and a p-doped pillar forming a super-junction structure on a substrate, the n-doped pillar and p-doped pillar each having a height perpendicular to the substrate and a lateral width parallel to the substrate, a lateral cross section of the n-doped pillar including a gate and at most one source; and
an isolation structure disposed in a trench between the n-doped pillar and the p-doped pillar.

2. The device of claim 1, wherein the trench has depth in a range of about 30 μm to 50 μm.

3. The device of claim 1, wherein the isolation structure includes an air gap disposed between the n-doped pillar and the p-doped pillar.

4. The device of claim 3, wherein an air gap is filled with a gas at atmospheric or sub-atmospheric pressures.

5. The device of claim 1, wherein an epi liner is disposed between the isolation structure and the n-doped pillar and between the isolation structure and the p-doped pillar.

6. The device of claim 5, wherein the epi liner when first formed is more lightly doped than the n-doped pillar and the p-doped pillar.

7. The device of claim 1, wherein the trench has an opening width at about the tops of the n-doped pillar and the p-doped pillar that is wider than an opening width of the trench in a lower body portion of the trench.

8. The device of claim 1, wherein a top of the n-doped pillar has a rounded shape.

9. The device of claim 1, wherein the isolation structure includes deposited silicon oxide.

10. The device of claim 9, wherein the deposited silicon oxide forms an oxide plug in an upper portion of the trench and encloses an air gap in a lower portion of the trench.

11. (canceled)

12. The device of claim 1, wherein the gate is disposed in a gate trench etched in the n-doped pillar, the gate trench having a pair of vertical sidewalls formed by material of the n-doped pillar.

13. A transistor comprising:
a first mesa stripe of a first conductivity type and a second mesa stripe of a second conductivity type disposed on a semiconductor substrate;
a gate disposed in a gate trench etched in a top of the first mesa stripe, the gate trench having sidewalls formed by material of the first mesa stripe; and
a sequence of source regions disposed on the top of the first mesa stripe at intervals along a length of the first mesa stripe, a first of the sequence of the source regions being disposed on one lateral side of the first mesa stripe and the next of the sequence of the source regions being disposed on an opposite lateral side of the first mesa stripe along the length of the first mesa stripe.

14. The transistor of claim 13, wherein a section of the gate trench is placed off-center on a first side of the top of the first mesa stripe.

15. The transistor of claim 14, wherein the gate trench shifts from the first side to another side of the first mesa stripe along a length of the first mesa stripe.

16. The transistor of claim 13, wherein a lateral cross section of the first mesa stripe perpendicular to the length of the first mesa stripe-includes the gate and at most one source region.

17. The transistor of claim 13 wherein the gate trench forms a gate trench loop on the top of the first mesa stripe.

18. A method, comprising:
disposing an n-doped column and a p-doped column on a substrate, the n-doped column and the p-doped column each having a respective initial column width and being separated by a trench having an initial trench width;
providing additional semiconductor real estate for fabricating device components in the n-doped column and p-doped column by depositing epitaxial material having an epi thickness on vertical sides of the columns to form an n-doped pillar and a p-doped pillar, the n-doped pillar and the p-doped pillar each having a respective pillar width greater than the respective initial column width, and the trench between the n-doped pillar and a p-doped pillar having a trench width smaller than the initial trench width;
disposing an isolation structure in the trench between the n-doped pillar and the p-doped pillar; and
disposing a source and a gate on the n-doped pillar.

19. The method of claim 18, wherein disposing the isolation structure in the trench between the n-doped pillar and the p-doped pillar includes disposing an oxide plug in the trench between the n-doped pillar and the p-doped pillar, the oxide plug capping the trench and encapsulating an air gap in the trench.

20. The method of claim 18, wherein disposing the isolation structure in the trench between the n-doped pillar and the p-doped pillar includes disposing an epi liner between the isolation structure and the n-doped pillar and between the isolation structure and the p-doped pillar.

21. The method of claim 18 wherein the n-doped pillar and the p-doped pillar each have a respective pillar width greater than about 1 micron, and the trench between the n-doped pillar and a p-doped pillar has a trench width smaller than about 0.5 microns.
